(19) United States
(12) Patent Application Publication
(10) Pub. No.: US 2023/0282675 A1
(43) Pub. Date: Sep. 7, 2023

(54) SOLID-STATE IMAGING DEVICE, ELECTRONIC DEVICE AND METHOD FOR MANUFACTURING SOLID-STATE IMAGING DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventor: Keisuke FUCHIDA, Fujisawa Kanagawa (JP)

(21) Appl. No.: 17/901,457

(22) Filed: Sep. 1, 2022

(30) Foreign Application Priority Data
Mar. 10, 2022 (JP) 2022-037532

(51) Int. Cl. H01L 27/146; H04N 5/33

(52) U.S. Cl. CPC H01L 27/14645; H01L 27/14621; H01L 27/14649; H01L 27/14685; H04N 5/33

(57) ABSTRACT

A solid-state imaging device includes a substrate having a major surface, a photodiode for near infrared light disposed on the major surface and configured to detect near infrared light, and a stacked filter disposed on the photodiode for near infrared light and configured to remove visible light. The stacked filter includes a red filter configured to transmit red light and the near infrared light and remove light other than the red light and the near infrared light, a green filter configured to transmit green light and the near infrared light and remove light other than the green light and the near infrared light, and a blue filter configured to transmit blue light and the near infrared light and remove light other than the blue light and the near infrared light. The red filter, the green filter, and the blue filter are stacked above the photodiode for near infrared light.

### CROSS-REFERENCE TO RELATED APPLICATION(S)

This application is based upon and claims the benefit of priority from Japanese Patent Application No. 2022-037532, filed Mar. 10, 2022, the entire contents of which are incorporated herein by reference.

### FIELD

Embodiments described herein relate generally to a solid-state imaging device, an electronic device and a method for manufacturing the solid-state imaging device.

### BACKGROUND

In order to accurately detect an intensity of light with a specific wavelength incident on a light receiving element (e.g., photodiode) corresponding to a pixel, a solid-state imaging device needs to block light having other wavelengths. In a solid-state imaging device in the related art, a filter that removes light having the other wavelengths with a wavelength generating noise is formed on a glass substrate, and the glass substrate is disposed above a light receiving element. A configuration of a solid-state imaging device according to a comparative example will be described with reference to FIG. 1.

FIG. 1 is a cross-sectional view showing a configuration of a solid-state imaging device 100 according to the comparative example. In the solid-state imaging device 100, a photodiode 103 for near infrared light, a photodiode 103a for red light, a photodiode 103b for green light and a photodiode 103c for blue light are provided on a substrate 102. A red filter 106 is formed on the photodiode 103a for red light, a green filter 107 is formed on the photodiode 103b for green light, and a blue filter 108 is formed on the photodiode 103c for blue light. As shown in FIG. 1, a glass substrate 109 on which a near infrared light cut filter 105 and a visible light cut filter 110 are formed, is disposed above the substrate 102. The glass substrate 109 is optically positioned with respect to the substrate 102.

As described above, in the solid-state imaging device 100 according to the comparative example, the glass substrate 109 on which the near infrared light cut filter 105 and the visible light cut filter 110 are formed is disposed above the photodiodes 103, 103a, 103b and 103c. Because the glass substrate is provided, the size of the solid-state imaging device becomes large. The cost of the solid-state imaging device increases due to the manufacturing cost of the glass substrate 109 on which the near infrared light cut filter and the visible light cut filter are mounted. As a result, it is difficult to downsize (e.g., thin) the solid-state imaging device due to the presence of the glass substrate 109. Further, there is also a problem that a light receiving sensitivity is lowered due to the interposition of the glass substrate.

### DESCRIPTION OF THE DRAWINGS

FIG. 1 is a cross-sectional view showing a configuration of a solid-state imaging device according to a comparative example.

FIG. 2 is a diagram illustrating an optical system in an electronic device according to an embodiment.

FIG. 3 is a plan view showing a configuration example of a solid-state imaging device according to the embodiment.

FIG. 4 is a cross-sectional view showing the configuration example of the solid-state imaging device according to the embodiment, and is a view of a cross-section taken along a line A-A in FIG. 3.

FIG. 5 is a graph showing an example of transmittance-wavelength dependencies of a filter used in the solid-state imaging device according to the embodiment.

FIG. 6A is a cross-sectional view illustrating an example of a method for manufacturing the solid-state imaging device according to the embodiment.

FIG. 6B is a view illustrating an example of the method for manufacturing the solid-state imaging device according to the embodiment, following FIG. 6A.

FIG. 6C is a view illustrating an example of the method for manufacturing the solid-state imaging device according to the embodiment, following FIG. 6B.

FIG. 6D is a view illustrating an example of the method for manufacturing the solid-state imaging device according to the embodiment, following FIG. 6C.

FIG. 6E is a view illustrating an example of the method for manufacturing the solid-state imaging device according to the embodiment, following FIG. 6D.

### DETAILED DESCRIPTION

Embodiments provide a highly-sensitive solid-state imaging device that is compact and low in cost, an electronic device, and a method for manufacturing the solid-state imaging device.

In general, according to one embodiment, the solid-state imaging device includes a substrate having a major surface, a photodiode for near infrared light disposed on the major surface and configured to detect near infrared light, and a RGB stacked filter disposed on the photodiode for near infrared light and configured to remove visible light. The stacked filter includes a first red filter configured to transmit red light and the near infrared light and remove light in a wavelength band other than the red light and the near infrared light, a first green filter configured to transmit green light and the near infrared light and remove light in the wavelength band other than the green light and the near infrared light, and a first blue filter configured to transmit blue light and the near infrared light and remove light in the wavelength band other than the blue light and the near infrared light. The first red filter, the first green filter, and the first blue filter are stacked above the photodiode for near infrared light.

Hereinafter, the embodiment according to the present disclosure will be described with reference to the drawings. The present embodiment is not intended to limit the present disclosure. The drawings are schematic or conceptual, and a proportion and the like of each portion are not necessarily the same as actual ones. In the description and the drawings, components similar to those previously described with reference to a preceding figure are denoted by the same reference numerals, and the detailed description thereof will be appropriately omitted.

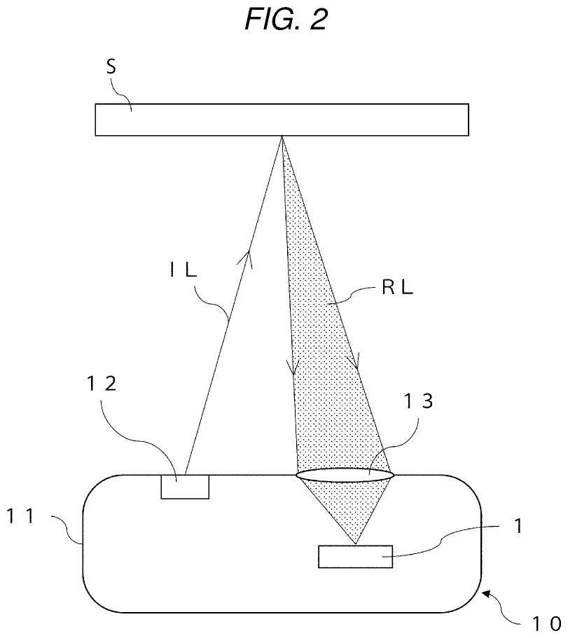

Electronic Device First, the electronic device according to the embodiment will be described with reference to FIG. 2. FIG. 2 shows an electronic device 10 and a subject S according to the present embodiment.

The electronic device 10 is configured to capture images of the subject S by emitting white light and near infrared light toward the subject S. For example, the electronic device 10 is a personal digital assistant such as a smartphone or a tablet terminal, or an inspection machine that inspects agricultural products such as grains.

As shown in FIG. 2, the electronic device 10 includes a solid-state imaging device 1, a housing 11, a light source unit 12, and a lens 13.

The housing 11 is provided with the solid-state imaging device 1, the light source unit 12 and the lens 13. Although not shown, the housing 11 is further provided with, for example, a display that outputs an image captured by the solid-state imaging device 1, a battery that supplies power to the solid-state imaging device 1 and the light source unit 12, and a communication module for communicating with an external device.

The light source unit 12 emits light toward the subject S outside the housing 11. In the present embodiment, the light source unit 12 includes a white light source (not shown) that emits white light and a near infrared light source (not shown) that emits near infrared light, and emits the white light and the near infrared light at the same time. For example, the white light is light in a wavelength band of about 200 nm to 800 nm, and for example, the near infrared light is light in a wavelength band of about 800 nm to 1200 nm.

The lens 13 converges the light emitted from the light source unit 12 and reflected by the subject S. The light converged by the lens 13 is received by the solid-state imaging device 1.

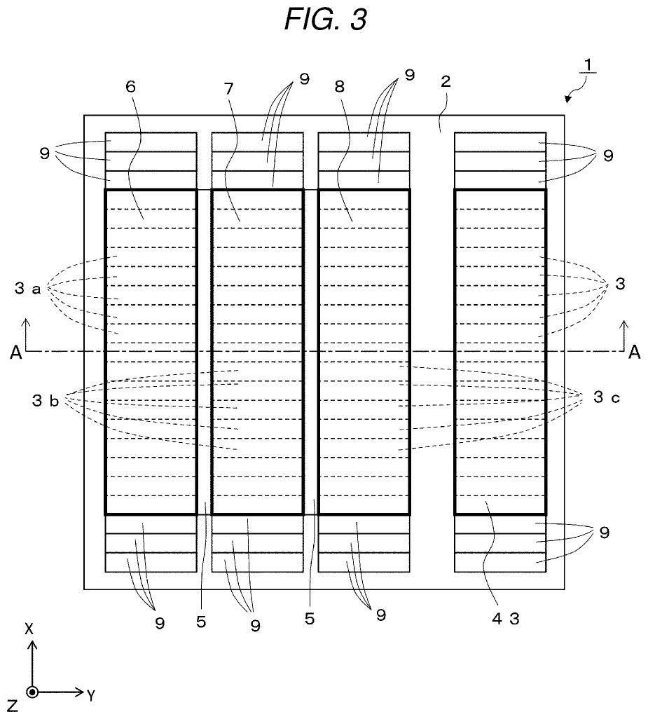

The solid-state imaging device 1 captures images of the subject S that is irradiated with visible light and near infrared light at the same time. Specifically, as shown in FIG. 2, emitted light IL emitted from the light source unit 12 is incident on the subject S, and a part of the emitted light IL is reflected. Reflected light (reflected light RL) is converged by the lens 13 of the electronic device 10, and is incident on the solid-state imaging device 1. In the present embodiment, the solid-state imaging device 1 is implemented as a linear image sensor as will be described later with reference to FIG. 3. Further, the solid-state imaging device according to the present embodiment is not limited to the linear image sensor, and may be an image sensor other than the linear image sensor.

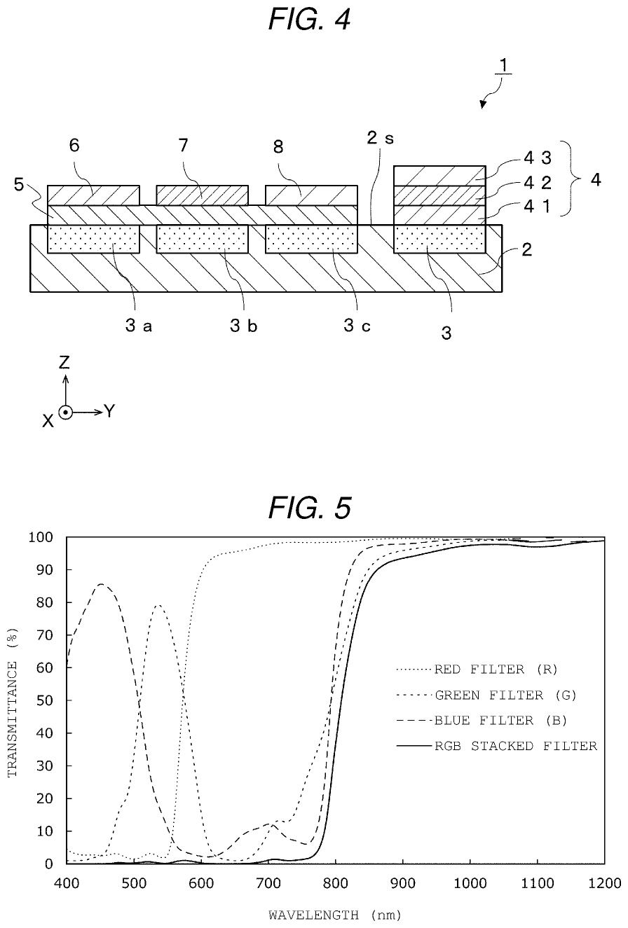

Solid-State Imaging Device Next, the solid-state imaging device 1 according to the embodiment will be described in detail with reference to FIGS. 3 and 4. FIG. 3 is a plan view of the solid-state imaging device 1, and shows an incidence surface side of the reflected light RL. FIG. 4 is a view of a cross-section taken along a line A-A of the solid-state imaging device 1 shown in FIG. 3.

For convenience of description, an XYZ orthogonal coordinate system is adopted as shown in FIGS. 3 and 4. A thickness direction of the solid-state imaging device 1, that is, a stacking direction of the substrate and the filters is set as a Z direction. Of directions that are approximately orthogonal to the Z direction, a direction in which the same type of photodiodes are arranged is set as an X direction, and a direction that is approximately orthogonal to the Z direction and the X direction is set as a Y direction. Further, in the Z direction, a direction from the substrate to the filters is also referred to as “upper”, and an opposite direction thereof is also referred to as “lower”. This expression is for convenience and is independent of the direction of gravity.

As shown in FIG. 4, the solid-state imaging device 1 includes a substrate 2, a photodiode 3 for near infrared light, a photodiode 3a for red light, a photodiode 3b for green light, a photodiode 3c for blue light, a RGB stacked filter 4, a near infrared light cut filter 5, a red filter 6, a green filter 7, and a blue filter 8.

Although not shown, a lid glass (cover glass) is disposed on an uppermost layer of the solid-state imaging device 1. This lid glass is provided not only to protect the solid-state imaging device, but also to remove ultraviolet light that causes a short life of the filters and noise.

Further, in the following description, the photodiode 3 for near infrared light, the photodiode 3a for red light, the photodiode 3b for green light and the photodiode 3c for blue light are collectively referred to as “photodiodes 3, 3a, 3b, and 3c”. The photodiode 3a for red light, the photodiode 3b for green light and the photodiode 3c for blue light are collectively referred to as “photodiodes 3a, 3b, and 3c”. The red filter 6, the green filter 7, and the blue filter 8 are collectively referred to as “color filters 6, 7, and 8”.

In the present embodiment, a red filter 41 and the red filter 6 have the same characteristics. Similarly, a green filter 42 and the green filter 7 have the same characteristics, and a blue filter 43 and the blue filter 8 have the same characteristics.

As shown in FIG. 4, the substrate 2 has a major surface 2s, and the photodiodes 3, 3a, 3b, and 3c are formed on the major surface 2s. The substrate 2 is, for example, a semiconductor substrate such as a silicon substrate or a silicon carbide substrate. Although not shown, various wirings are formed in the substrate 2. The substrate 2 may be a multilayer substrate including an insulating layer and the like.

As shown in FIG. 3, a plurality of photodiodes of the same type are arranged on a straight line parallel to an X axis direction of the substrate 2 to form a pixel array. Further, pixel arrays of the colors are arranged at predetermined intervals in a Y axis direction. Pixels at ends of the pixel arrays are covered with a metal film and are used as light-shielding pixels 9. The pixels in the pixel arrays other than the light-shielding pixels 9 are covered with filters. That is, a plurality of pixels in a red pixel array other than the light-shielding pixels 9 are covered with the red filter 6. Similarly, a plurality of pixels in a green pixel array other than the light-shielding pixels 9 are covered with the green filter 7, and a plurality of pixels in a blue pixel array other than the light-shielding pixels 9 are covered with the blue filter 8.

The photodiode 3 for near infrared light is a photodiode that detects near infrared light (for example, light in a wavelength band of about 800 nm to 1200 nm). The photodiode 3a for red light is a photodiode that detects red light (for example, light in a wavelength band of about 580 nm to 800 nm). The photodiode 3b for green light is a photodiode that detects green light (for example, light in a wavelength band of about 500 nm to 580 nm). The photodiode 3c for blue light is a photodiode that detects blue light (for example, light in a wavelength band of about 400 nm to 500 nm).

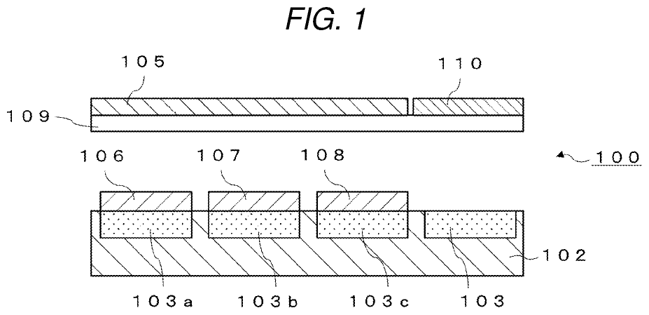

As described with reference to FIG. 1, in a solid-state imaging device according to a comparative example, by placing a visible light cut filter above the photodiode for near infrared light, the photodiode for near infrared light receives near infrared light from which visible light is removed. In contrast, in the present embodiment, as shown in FIGS. 3 and 4, instead of the visible light cut filter, the RGB stacked filter 4 is disposed on the photodiode 3 for near infrared light. The RGB stacked filter 4 is implemented by stacking the red filter 41, the green filter 42, and the blue filter 43, and effectively removes the visible light. The RGB stacked filter 4 will be described in more detail below.

In the RGB stacked filter 4 according to the present embodiment, as shown in FIG. 4, the red filter 41 is stacked on the photodiode 3 for near infrared light, the green filter 42 is stacked on the red filter 41, and the blue filter 43 is stacked on the green filter 42. A stacking order is not limited thereto, and the RGB stacked filter 4 may be implemented by stacking the red filter 41, the green filter 42 and the blue filter 43 in any order.

Here, characteristics of the RGB stacked filter 4 will be described. FIG. 5 is a graph showing an example of transmittance-wavelength dependencies of the red filters 6 and 41, the green filters 7 and 42, and the blue filters 8 and 43 that are used in the solid-state imaging device 1 according to the present embodiment.

As can be seen from FIG. 5, the red filter 41 has a characteristic of transmitting the red light and the near infrared light, and removing light in a wavelength band other than the red light and the near infrared light. Further, the green filter 42 has a characteristic of transmitting the green light and the near infrared light, and removing light in a wavelength band other than the green light and the near infrared light. The blue filter 43 has a characteristic of transmitting the blue light and the near infrared light, and removing light in a wavelength band other than the blue light and the near infrared light.

Further, as can be seen from FIG. 5, the RGB stacked filter 4, in which the red filter 41, the green filter 42 and the blue filter 43 are stacked, effectively removes the visible light and transmits the near infrared light. That is, it can be seen that the RGB stacked filter 4, which is implemented by stacking the red filter 41, the green filter 42 and the blue filter 43, has the same characteristics as the visible light cut filter.

As shown in FIG. 4, the near infrared light cut filter 5 is disposed such that the photodiodes 3a, 3b, and 3c are covered. The near infrared light cut filter 5 has a characteristic of removing the near infrared light, and transmitting light in a wavelength band other than the near infrared light. Accordingly, the photodiodes 3a, 3b, and 3c receive the visible light from which the near infrared light is removed.

The red filter 6 is disposed on the near infrared light cut filter 5 above the photodiode 3a for red light. The green filter 7 is disposed on the near infrared light cut filter 5 above the photodiode 3b for green light. The blue filter 8 is disposed on the near infrared light cut filter 5 above the photodiode 3c for blue light.

The light-shielding pixels 9 shown in FIG. 3 are pixels used for dark correction. A light-shielding film (not shown) made of a metal such as aluminum is disposed on the photodiodes of the light-shielding pixel 9 instead of the filters.

The solid-state imaging device 1 having the configuration described above receives the reflected light RL from the subject S by the photodiodes 3, 3a, 3b, and 3c. Further, the solid-state imaging device 1 obtains color images of the subject S based on light reception signals of the photodiodes 3a, 3b, and 3c. At the same time, the solid-state imaging device 1 obtains a near infrared image of the subject S based on a signal of the photodiode 3. In addition, the solid-state imaging device 1 may be configured to measure a distance from the electronic device 10 to the subject S based on a time period that starts when the near infrared light is emitted from the light source unit 12 and ends when the near infrared light is reflected by the subject S and received by the photodiode 3.

As described above, in the solid-state imaging device 1, a stack of the red filter 41, the green filter 42, and the blue filter 43 is provided on the photodiode 3 for near infrared light. Thus, unlike a solid-state imaging device according to the comparative example, the visible light toward the photodiode 3 for near infrared light can be effectively removed without using the visible light cut filter.

According to the present embodiment, unlike the solid-state imaging device according to the comparative example, it is not necessary to dispose a glass substrate on which the visible light cut filter is formed above the photodiode 3 for near infrared light. Therefore, an optical position adjustment becomes unnecessary, and an optical system can be downsized (e.g., thinned). In addition, since the filters are directly stacked on the photodiodes, resistance against an impact can be improved.

According to the present embodiment, unlike the solid-state imaging device according to the comparative example, since the glass substrate is not interposed between the lens and a light receiving element, the light receiving sensitivity can be improved. Further, in the present embodiment, the near infrared light cut filter 5 is covered by the color filters 6, 7 and 8, and the near infrared light cut filter 5 is not directly exposed to the reflected light RL. Therefore, light resistance (UV resistance or the like) of the near infrared light cut filter 5 can be improved.

FIGS. 3 and 4 are merely examples of the configuration of the solid-state imaging device 1. For example, an arrangement order of the red filter 41, the green filter 42 and the blue filter 43 may be set freely as described above, and the RGB stacked filter 4 may be implemented by stacking the red filter 41, the green filter 42, and the blue filter 43 in an order different from the order described above.

In the present embodiment, as shown in FIG. 3, the photodiodes are arranged in the straight line for each type, and the arrangement is not limited thereto. Alternatively, for example, the photodiode 3a for red light, the photodiode 3b for green light, and the photodiode 3c for blue light may be arranged according to a Bayer arrangement.

When a decrease in the light resistance of the near infrared light cut filter 5 is not taken into consideration, an upper-lower arrangement relation between the near infrared light cut filter 5 and the color filters 6, 7 and 8 may be reversed from the above. That is, the red filter 6 may be disposed on the photodiode 3a for red light, the green filter 7 may be disposed on the photodiode 3b for green light, the blue filter 8 may be disposed on the photodiode 3c for blue light, and the near infrared light cut filter 5 may be disposed to cover the red filter 6, the green filter 7 and the blue filter 8.

In the above description, the near infrared light cut filter 5 covers the photodiodes 3a, 3b, and 3c of the colors. Alternatively, the near infrared light cut filter may be separated into sections each of which is disposed on one of the photodiodes 3a, 3b, and 3c of the colors.

In the above solid-state imaging device 1, the photodiodes 3a, 3b, and 3c that detect the red light, the green light, and the blue light, respectively, and the photodiode 3 that detects the near infrared light are provided. Alternatively, the photodiode 3 may be provided alone. In such a case, the light source unit 12 emits only the near infrared light.

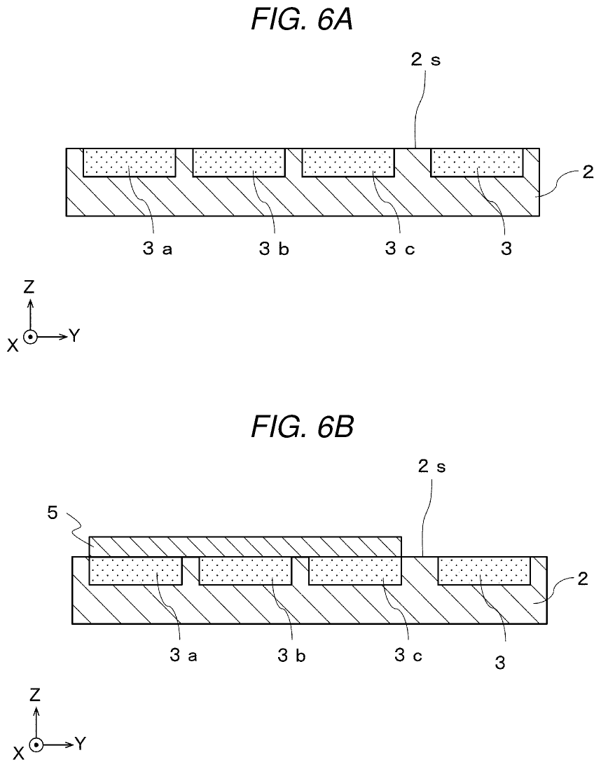

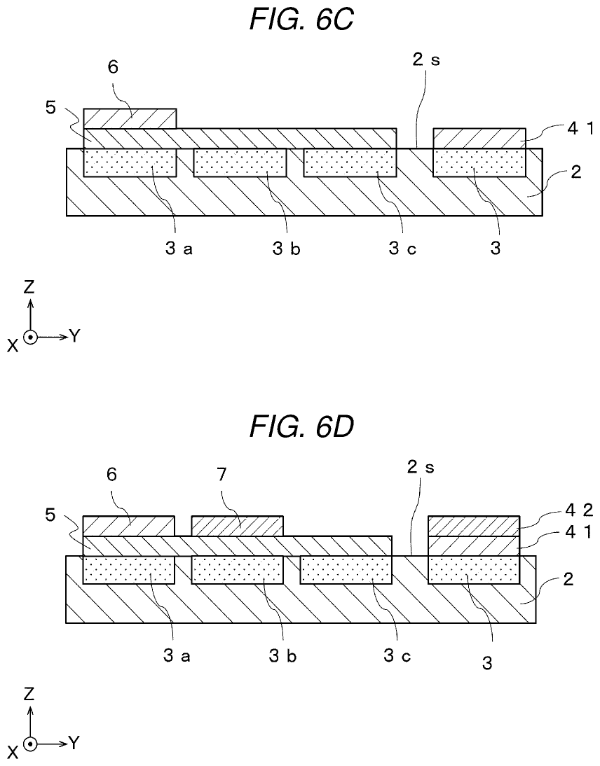

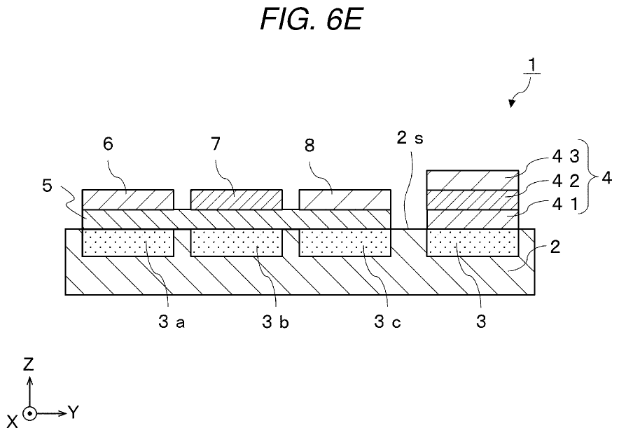

Method for Manufacturing Solid-State Imaging Device Next, an example of the method for manufacturing the above solid-state imaging device 1 will be described with reference to FIGS. 6A to 6E. FIGS. 6A to 6E are cross-sectional views illustrating the method for manufacturing the solid-state imaging device 1.

First, the substrate 2 having the major surface 2s is prepared. For example, the semiconductor substrate made of silicon (Si), silicon carbide (SiC) or the like is used as the substrate 2.

Next, As shown in FIG. 6A, the photodiode 3 for near infrared light, the photodiode 3a for red light, the photodiode 3b for green light and the photodiode 3c for blue light are formed on the major surface 2s of the substrate 2. In the present embodiment, the photodiodes 3, 3a, 3b, and 3c are formed such that the photodiodes of the same type are arranged on the straight line parallel to the X axis direction. In addition, the arrangement of the formed photodiodes 3, 3a, 3b, and 3c is determined according to the type of the image sensor, and is not limited to the case in which the photodiodes are arranged along a straight line.

As shown in FIG. 6B, the near infrared light cut filter 5 is formed on the photodiode 3a for red light, the photodiode 3b for green light and the photodiode 3c for blue light. The near infrared light cut filter 5 is formed as an on-chip infrared light cut filter. In detail, the near infrared light cut filter 5 is formed by depositing a filter material on the photodiodes 3a, 3b, and 3c by physical vapor deposition (PVD) or chemical vapor deposition (CVD), or by applying the filter material on the photodiodes 3a, 3b, and 3c.

The near infrared light cut filter 5 may not be integrally formed. For example, separate sections of the near infrared light cut filter may be formed on the photodiode 3a for red light, the photodiode 3b for green light, and the photodiode 3c for blue light, respectively.

Next, as shown in FIG. 6C, the red filter 41 is formed on the photodiode 3 for near infrared light. The red filter 41 is formed as an on-chip color filter. A formation method thereof is the same as that of the near infrared light cut filter 5.

In the present embodiment, the red filter 6 is formed in the same step as a formation step of the red filter 41. That is, the red filter 41 and the red filter 6 are formed at the same time. The red filter 6 is formed on the near infrared light cut filter 5 above the photodiode 3a for red light.

Next, as shown in FIG. 6D, the green filter 42 is formed on the red filter 41. A formation method of the green filter 42 is the same as that of the near infrared light cut filter 5 and the red filter 41. In the present embodiment, the green filter 7 is formed in the same step as a formation step of the green filter 42. The green filter 7 is formed on the near infrared light cut filter 5 above the photodiode 3b for green light.

Finally, as shown in FIG. 6E, the blue filter 43 is formed on the green filter 42. A formation method of the blue filter 43 is the same as that of the near infrared light cut filter 5, the red filter 41 and the green filter 42. In the present embodiment, the blue filter 8 is formed in the same step as a formation step of the blue filter 43. The blue filter 8 is formed on the near infrared light cut filter 5 above the photodiode 3c for blue light.

The solid-state imaging device 1 shown in FIG. 6E is manufactured by the above steps.

The above description is merely an example of the method for manufacturing the solid-state imaging device 1. For example, the order in which the filters of the colors are stacked may be set freely.

As described above, in the method for manufacturing the solid-state imaging device 1 according to the present embodiment, a filter having the same performances as the visible light cut filter can be formed by sequentially stacking the red filter 41, the green filter 42, and the blue filter 43. Therefore, a material and a formation step for forming the visible light cut filter are not required, and the manufacturing cost of the solid-state imaging device can be reduced.

Since the color filters 6, 7, and 8 can be formed in a step of forming the RGB stacked filter 4, the solid-state imaging device can be manufactured efficiently and at low cost.

The color filters 6, 7 and 8 are stacked on the near infrared light cut filter 5, so that the near infrared light cut filter 5 is not directly exposed to the reflected light RL. Therefore, the light resistance of the near infrared light cut filter 5 can be improved.

According to the present embodiment, unlike the solid-state imaging device according to the comparative example, it is not necessary to form the near infrared light cut filter and the visible light cut filter on the glass substrate. Therefore, no difficulties occur in ensuring position dimension accuracy when these filters are formed on the glass substrate and in the optical position adjustment between the glass substrate and the substrate. As a result, the yield of the solid-state imaging device can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A solid-state imaging device comprising:
a substrate having a major surface;
a photodiode for near infrared light disposed on the major surface and configured to detect near infrared light; and
a stacked filter disposed on the photodiode for near infrared light and configured to remove visible light, wherein
the stacked filter includes a first red filter configured to transmit red light and the near infrared light and remove light in a wavelength band other than the red light and the near infrared light, a first green filter configured to transmit green light and the near infrared light and remove light in the wavelength band other than the green light and the near infrared light, and a first blue filter configured to transmit blue light and the near infrared light and remove light in the wavelength band other than the blue light and the near infrared light, and the first red filter, the first green filter, and the first blue filter are stacked above the photodiode for near infrared light.

2. The solid-state imaging device according to claim 1, further comprising:
a photodiode for red light disposed on the major surface of the substrate and configured to detect red light;
a photodiode for green light disposed on the major surface and configured to detect green light;
a photodiode for blue light disposed on the major surface and configured to detect blue light;
a near infrared light cut filter configured to remove near infrared light that is directed toward the photodiode for red light, the photodiode for green light and the photodiode for blue light;
a second red filter configured to transmit red light toward the photodiode for red light;
a second green filter configured to transmit green light toward the photodiode for green light; and
a second blue filter configured to transmit blue light toward the photodiode for blue light.

3. The solid-state imaging device according to claim 2, wherein
the near infrared light cut filter covers the photodiode for red light, the photodiode for green light and the photodiode for blue light,
the second red filter is disposed on the near infrared light cut filter above the photodiode for red light,
the second green filter is disposed on the near infrared light cut filter above the photodiode for green light, and
the second blue filter is disposed on the near infrared light cut filter above the photodiode for blue light.

4. The solid-state imaging device according to claim 3, wherein the near infrared light cut filter is integrally formed.

5. The solid-state imaging device according to claim 3, wherein the first and second red filters have the same light filtering characteristics, the first and second green filters have the same light filtering characteristics, and the first and second blue filters have the same light filtering characteristics.

6. The solid-state imaging device according to claim 1, wherein
the first red filter is stacked on the photodiode for near infrared light,
the first green filter is stacked on the first red filter, and
the first blue filter is stacked on the first green filter.

7. The solid-state imaging device according to claim 1, further comprising:
a plurality of additional photodiodes for near infrared light disposed on the major surface and aligned along a first direction;
a plurality of photodiodes for red light disposed on the major surface of the substrate, aligned along the first direction, and configured to detect red light;
a plurality of photodiodes for green light disposed on the major surface, aligned along the first direction, and configured to detect green light; and
a plurality of photodiodes for blue light disposed on the major surface, aligned along the first direction, and configured to detect blue light.

8. An electronic device comprising:
a housing;
a light source configured to emit light toward a subject;
a lens configured to converge light emitted from the light source unit and reflected by the subject; and
a solid-state imaging device arranged to receive the light converged by the lens, wherein the solid-state imaging device includes:
a substrate having a major surface;
a photodiode for near infrared light disposed on the major surface and configured to detect near infrared light; and
a stacked filter disposed on the photodiode for near infrared light and configured to remove visible light, and wherein
the stacked filter includes a first red filter configured to transmit red light and the near infrared light and remove light in a wavelength band other than the red light and the near infrared light, a first green filter configured to transmit green light and the near infrared light and remove light in the wavelength band other than the green light and the near infrared light, and a first blue filter configured to transmit blue light and the near infrared light and remove light in the wavelength band other than the blue light and the near infrared light, and the first red filter, the first green filter, and the first blue filter are stacked above the photodiode for near infrared light.

9. The electronic device according to claim 8, wherein the solid-state imaging device further includes:
a photodiode for red light disposed on the major surface of the substrate and configured to detect red light;
a photodiode for green light disposed on the major surface and configured to detect green light;
a photodiode for blue light disposed on the major surface and configured to detect blue light;
a near infrared light cut filter configured to remove near infrared light that is directed toward the photodiode for red light, the photodiode for green light and the photodiode for blue light;
a second red filter configured to transmit red light toward the photodiode for red light;
a second green filter configured to transmit green light toward the photodiode for green light; and
a second blue filter configured to transmit blue light toward the photodiode for blue light.

10. The electronic device according to claim 9, wherein
the near infrared light cut filter covers the photodiode for red light, the photodiode for green light and the photodiode for blue light,
the second red filter is disposed on the near infrared light cut filter above the photodiode for red light, the second green filter is disposed on the near infrared light cut filter above the photodiode for green light, and
the second blue filter is disposed on the near infrared light cut filter above the photodiode for blue light.

11. The electronic device according to claim 10, wherein the near infrared light cut filter is integrally formed.

12. The electronic device according to claim 10, wherein the first and second red filters have the same light filtering characteristics, the first and second green filters have the same light filtering characteristics, and the first and second blue filters have the same light filtering characteristics.

13. The electronic device according to claim 8, wherein the solid-state imaging device further includes:
a plurality of additional photodiodes for near infrared light disposed on the major surface and aligned along a first direction;
a plurality of photodiodes for red light disposed on the major surface of the substrate, aligned along the first direction, and configured to detect red light;
a plurality of photodiodes for green light disposed on the major surface, aligned along the first direction, and configured to detect green light; and
a plurality of photodiodes for blue light disposed on the major surface, aligned along the first direction, and configured to detect blue light.

14. The electronic device according to claim 8, wherein
the first red filter is stacked on the photodiode for near infrared light,
the first green filter is stacked on the first red filter, and
the first blue filter is stacked on the first green filter.

15. The electronic device according to claim 8, wherein
the light source emits white light and near infrared light at the same time.

16. The electronic device according to claim 8, wherein
the solid-state imaging device is configured to measure a distance from the electronic device to the subject based on a time period that starts when near infrared light is emitted from the light source and ends when the near infrared light is reflected by the subject and received by the photodiode for near infrared light.

17. A method for manufacturing a solid-state imaging device, the method comprising:
preparing a substrate having a major surface;
forming, on the major surface of the substrate, a photodiode for near infrared light configured to detect near infrared light, a photodiode for red light configured to detect red light, a photodiode for green light configured to detect green light, and a photodiode for blue light configured to detect blue light;
forming a near infrared light cut filter configured to remove near infrared light to cover the photodiode for red light, the photodiode for green light and the photodiode for blue light;
forming first and second red filters configured to transmit red light and the near infrared light and remove light in a wavelength band other than the red light and the near infrared light, the first red filter being formed on the photodiode for near infrared light and the second red filter being formed above the photodiode for red light;
forming first and second green filters configured to transmit green light and the near infrared light and remove light in the wavelength band other than the green light and the near infrared light, the first green filter being formed on the first red filter and the second green filter being formed above the photodiode for green light; and
forming first and second blue filters configured to transmit blue light and the near infrared light and remove light in the wavelength band other than the blue light and the near infrared light, the first blue filter being formed on the first green filter and the second blue filter being formed above the photodiode for blue light.

18. The method for manufacturing a solid-state imaging device according to claim 17, wherein
the first red filter and the second red filter are formed in the same step,
the first green filter and the second green filter are formed in the same step, and
the first blue filter and the second blue filter are formed in the same step.

19. The method for manufacturing a solid-state imaging device according to claim 17, wherein the near infrared light cut filter is integrally formed.

20. The method for manufacturing a solid-state imaging device according to claim 17, said method further comprising:
forming a plurality of additional photodiodes for near infrared light disposed on the major surface and aligned along a first direction;
forming a plurality of additional photodiodes for red light disposed on the major surface of the substrate, aligned along the first direction, and configured to detect red light;
forming a plurality of additional photodiodes for green light disposed on the major surface, aligned along the first direction, and configured to detect green light; and
forming a plurality of additional photodiodes for blue light disposed on the major surface, aligned along the first direction, and configured to detect blue light.
